(19) United States
(12) Patent Application Publication
(10) Pub. No.: US 2008/0090311 A1
(43) Pub. Date: Apr. 17, 2008

(54) DIPPING DETECTING DEVICE FOR FABRICATING A SEMICONDUCTOR DEVICE

(75) Inventors: Dong-joo ROH, Cheonan-si (KR); Yong-kyun SUN, Cheonan-si (KR); Youn-sung KO, Cheonan-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Gyeonggi-do (KR)

(21) Appl. No.: 11/858,284

(22) Filed: Sep. 20, 2007

(30) Foreign Application Priority Data
Sep. 21, 2006 (KR) 1020060091693

(51) Int. Cl. H01L 21/66; C23C 16/00

(52) U.S. Cl. 438/10; 118/697; 257/E21.531

(57) ABSTRACT

A dipping detecting device used in the fabrication of semiconductor devices. The dipping detecting device includes a gripper used as a conductive first electrode and configured to pick up a semiconductor device in order to dip the semiconductor device into a dipping solution. A conductor used as a second electrode and formed at a side of the gripper. The conductor electrically insulated from the gripper. A power source unit applying a power to the gripper and the conductor and detecting a current flow, wherein a dipping state of the semiconductor device is detected depending on the flow of current.

### CROSS-REFERENCE TO RELATED APPLICATION

This U.S. non-provisional patent application claims priority under 35 U.S.C § 119 of Korean Patent Application 10-2006-0091693 filed on Sep. 21, 2006, the entire contents of which are hereby incorporated by reference.

### BACKGROUND OF THE INVENTION

1. Field of the Invention

Embodiments of the invention relate to the fabrication of semiconductor devices. More particularly, embodiments of the invention relate to a dipping detecting device for preventing poor dipping from occurring during the semiconductor fabrication process.

2. Discussion of Related Art

In order to increase the capacity and yields of semiconductor devices, processes of stacking component packages that are assembled and inspection-completed have been recently introduced. Such package stacking processes include a reform process of reforming leads of a package to be stacked; a stack and tack process of stacking a bottom package and a top package using an epoxy adhesive; a soldering process of soldering leads between bottom and top packages to electrically connect the bottom and top packages; and a post rinsing process for rinsing pollutants of a product caused by flux used in the soldering process. The soldering process is conventionally performed using a dipping method. In this process, semiconductor packages are dipped into flux, preheated, and dipped into a solder to be soldered. In detail, a gripper picks up semiconductor packages that are to be soldered, moves the packages into a flux pot or a solder pot, and lowers them to a predetermined position in the flux or solder pot. A flux or solder is supplied through nozzles so that the semiconductor packages can be dipped into the flux and/or solder.

The semiconductor packages may have good or poor soldering quality depending on exactly how the semiconductor packages are dipped into the flux or solder. If solder is insufficiently coated or not coated on the leads of the device then the semiconductor packages are poorly soldered. However, conventional dipping soldering equipment does not include an apparatus for checking the dipping state of the semiconductor package into the flux or solder. Rather, present auto inspection processes require visual inspection to determine the quality of the soldering process.

In addition, the soldering process is not inspected until after the dipping process so that the dipping process continues on other semiconductor packages even when poor dipping occurs. Thus, many semiconductor packages that have been poorly soldered continue to be mass-produced impacting manufacturing yields. Poor dipping may occur due to the height level of a flux in a flux pot or the level of solder in a solder pot caused by an inappropriate amount of flux or solder supplied through nozzles of a pump system. Also, poor dipping may be caused by the gripper not being positioned low enough in the dipping solution. Accordingly, an automated method of checking and correcting a dipping level and/or the positioning of a gripper in a semiconductor fabrication process is required.

### SUMMARY OF THE INVENTION

Exemplary embodiments of the present invention are directed to a dipping detecting device used in a semiconductor manufacturing process. In an exemplary embodiment, the dipping detecting device includes a gripper, a conductor, and a power source unit. The gripper is used as a conductive first electrode and is configured to pick up the semiconductor device for dipping into a dipping solution. The conductor is used as a second electrode, is formed at a side of the gripper and is electrically insulated from the gripper. The power source unit applies a power to the gripper and the conductor. The power source unit is configured to detect a current flow wherein a dipping state of the semiconductor device is detected depending on whether current flows between the conductor and the gripper when the semiconductor device is dipped in the dipping solution. The semiconductor device may be a semiconductor package that is to be soldered and the dipping solution may be a conductive liquid flux and a liquid solder. A lower part of the conductor may contact the dipping solution when an entire part of the semiconductor device is dipped into the dipping solution.

### BRIEF DESCRIPTION OF THE DRAWINGS

FIG. 1 is a schematic view illustrating a dipping detecting device according to an embodiment of the present invention;

FIG. 2 illustrates the dipping detecting device utilizing a power source unit having a programmable logical controller (PLC) module according to an embodiment of the present invention;

FIG. 3 illustrates the dipping detecting device utilizing a power source unit having an input/output board (I/O) device according to an embodiment of the present invention;

FIG. 4 illustrates the dipping detecting device utilizing a power source unit including a capacitor and an (I/O) device according to an embodiment of the present invention;

FIG. 5 illustrates dipping equipment including a dipping detecting device according to an embodiment of the present invention; and

FIG. 6 is a flowchart illustrating a method of detecting a dipping state of a semiconductor device utilizing a dipping detecting device according to an embodiment of the present invention.

### DESCRIPTION OF EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, like numbers refer to like elements throughout.

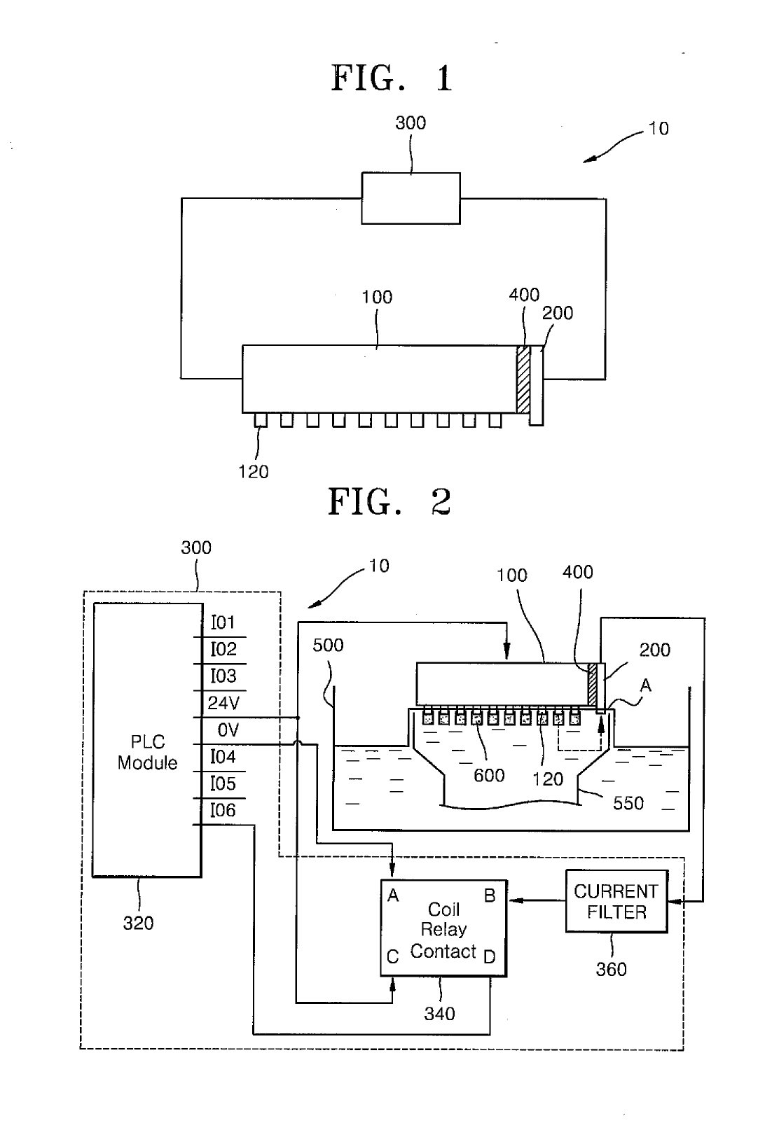

FIG. 1 is a schematic view of a dipping detecting device 10 configured to pick up a semiconductor device and dip it into a dipping solution. The dipping device 10 includes a gripper 100 for a conductive first electrode, a conductor 200 for a second electrode, and a power source unit 300. Conductor 200 is formed at a side of gripper 100. Power source unit 300 applies power (or a voltage) to conductor 200 and insulator 400 electrically insulates gripper 100 and conductor 200. Power source unit 300 may apply AC power or DC power to gripper 100 and conductor 200. Gripper 100 includes a plurality of gripper pickup units 120 formed of a conductor and used to pick up a plurality of semiconductor devices. When gripper 100 picks up a semiconductor device and dips the semiconductor device into a dipping solution through the use of gripper pickup units 120, power source unit 300 applies power to conductor 200 to detect whether the semiconductor device has been dipped into the dipping solution depending on whether current flows between conductor 200 and gripper 100. Thus, the dipping solution must be conductive and a lower part of conductor 200 must contact the dipping solution when the semiconductor device is dipped into the dipping solution. For example, during a soldering process a semiconductor device (e.g., a semiconductor package) is generally dipped into flux or solder where each has a conductive property. The lower part of conductor 200 must contact the flux or the solder when a top lead of the semiconductor package is completely dipped in a dipping process. Power source unit 300 may include a detecting part to detect whether current flows during the dipping process or may include a warning device to alert if a dipping error occurs where current does not flow. Thus, a dipping state can be easily detected in the dipping process depending on current flow.

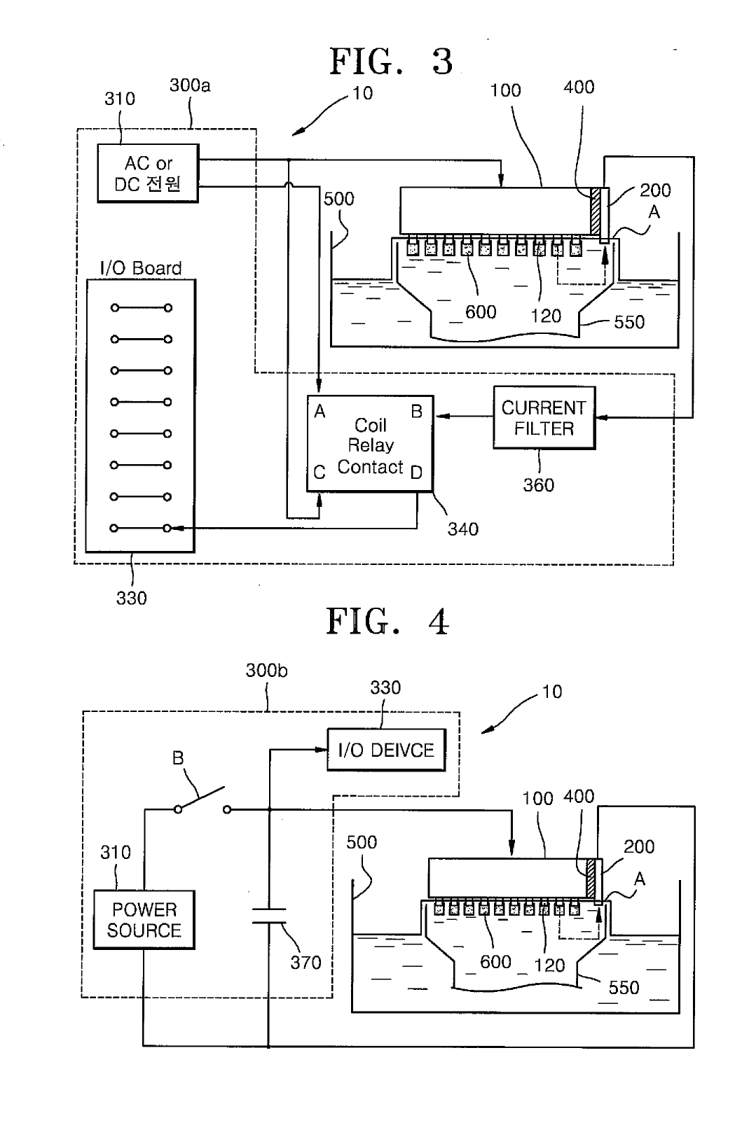

FIG. 2 illustrates the detecting dipping device 10 employing power source unit 300 including programmable logical controller (PLC) module 320. Gripper 100 picks up a plurality of semiconductor packages 600 with pick up units 120 and lowers them into a predetermined position in a dipping pot 500. The dipping solution ascends up through dipping solution nozzles 550 of dipping pot 500 in order to maintain a constant solution surface level indicated by reference A.

When the semiconductor packages 600 are dipped, conductor 200 contacts the solution and if power source unit 300 applies a power to gripper 100 and conductor 200, current flows through the dipping solution as indicated by the dotted arrow. Power source unit 300 includes PLC module 320, relay switch 340, and current filter 360. PLC module 320 applies power to gripper 100 and conductor 200 and detects current flow. Because semiconductor packages 600 are respectively dipped into different dipping solutions, the conductivity of the dipping solutions varies. Thus, power source unit 300 includes relay switch 340 and current filter 360 to detect an exact current flow. Current filter 360 includes a variable resistor to maintain a constant voltage applied to relay switch 340. Relay switch 340 includes a coil part and a switch part to be switched on or off depending on whether current flows to PLC module 320.

PLC module 320 includes a positive terminal (e.g., a 24V terminal) which is connected to both gripper 100 and terminal C of the switch part of relay switch 340. PLC module 320 also includes a negative terminal (e.g., a ground terminal) which is connected to terminal A of the coil part of relay switch 340. Conductor 200 is connected to terminal B of the coil part of relay switch 340 through current filter 360. Terminal D of the switch part of relay switch 340 is connected to detection terminal I06 of PLC module 320. In normal operation, current applied from the positive terminal of PLC module 320 flows between gripper 100 and conductor 200 through the dipping solution. The current having a constant voltage is applied to the coil part of relay switch 340 from conductor 200 through current filter 360 and a switch is turned on due to electromagnetism. The detection part of PLC module 320 detects a current signal. If the dipping states of the semiconductor packages 600 are not normal, current does not flow into the detection part of PLC module 320 and the dipping states of semiconductor packages 600 are detected as poor.

FIG. 3 illustrates the dipping detecting device 10 utilizing power source unit 300a that includes power source device 310 and input/output (I/O) device 330. Power source device 310 independently applies power (e.g. a source voltage) and I/O device 330 detects the applied signal. Power source unit 300a may further include current filter 360 and relay switch 340 to exactly detect whether current flows. Power source device 310 may be an AC or DC power source device and the wiring state may be the same as that described with reference to FIG. 2. However, the wiring state of the present embodiment is different from that of the embodiment of FIG. 2 in that power source device 310 is used instead of the power source part of PLC module 320 and current is detected through I/O device 330 rather than the detection part of PLC module 320.

FIG. 4 illustrates a power source unit 300b that includes power source device 310, capacitor 370 and I/O device 330. Power source unit 300b does not include relay switch 340 and current filter 360 as shown in FIG. 2 or 3. In addition, power source unit 300b detects current flow according to a different principle from that described in the embodiments of FIG. 2 or 3. In particular, a positive terminal of power source device 310 is connected to a first terminal of capacitor 370 and gripper 100 via switch B. A ground terminal of power source device 310 is connected to a second terminal of capacitor 370 and conductor 200. The first terminal of capacitor 370 is also connected to I/O device 300 that detects current flow. When a dipping process is not being performed, switch B is turned on and capacitor 370 is charged to a predetermined voltage and gripper 100 and conductor 200 are turned off. I/O device 330 may be directly connected to capacitor 370 as shown or a switch which turns I/O device 330 off so as to efficiently charge the capacitor 370 may be disposed between I/O device 330 and capacitor 370.

When the dipping process is performed, switch B is turned off and capacitor 370 applies power to gripper 100 and conductor 200. If the dipping state is normal, current flows and a voltage of capacitor 370 gradually falls. I/O device 330 detects the voltage drop of capacitor 370 and the dipping process is detected as performed normally. If the voltage of capacitor 370 does not drop during the dipping process, current is intercepted between gripper 100 and conductor 200 indicating an abnormal dipping state of the semiconductor device. In addition, dipping detector device of FIG. 4 may also include a relay switch and current filter as shown in FIGS. 2 and 3 as well as a signal detector (not shown).

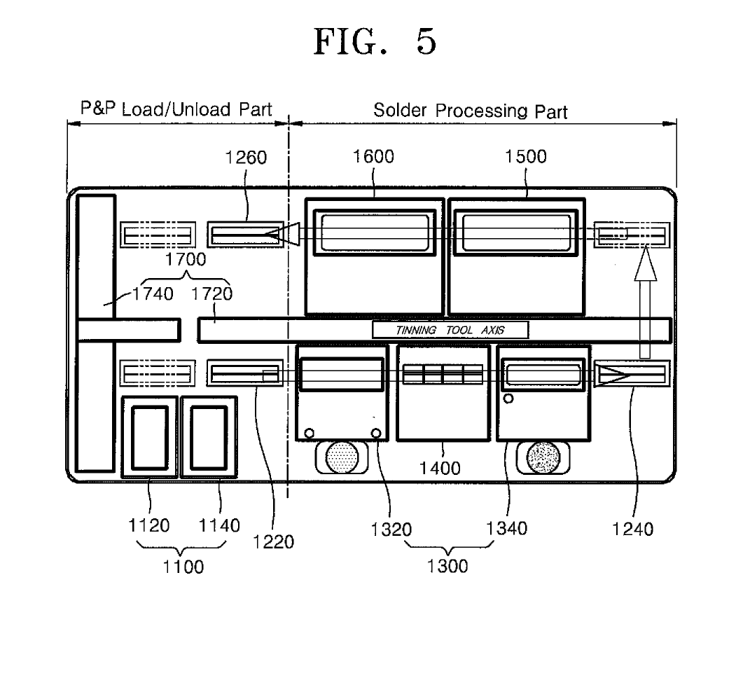

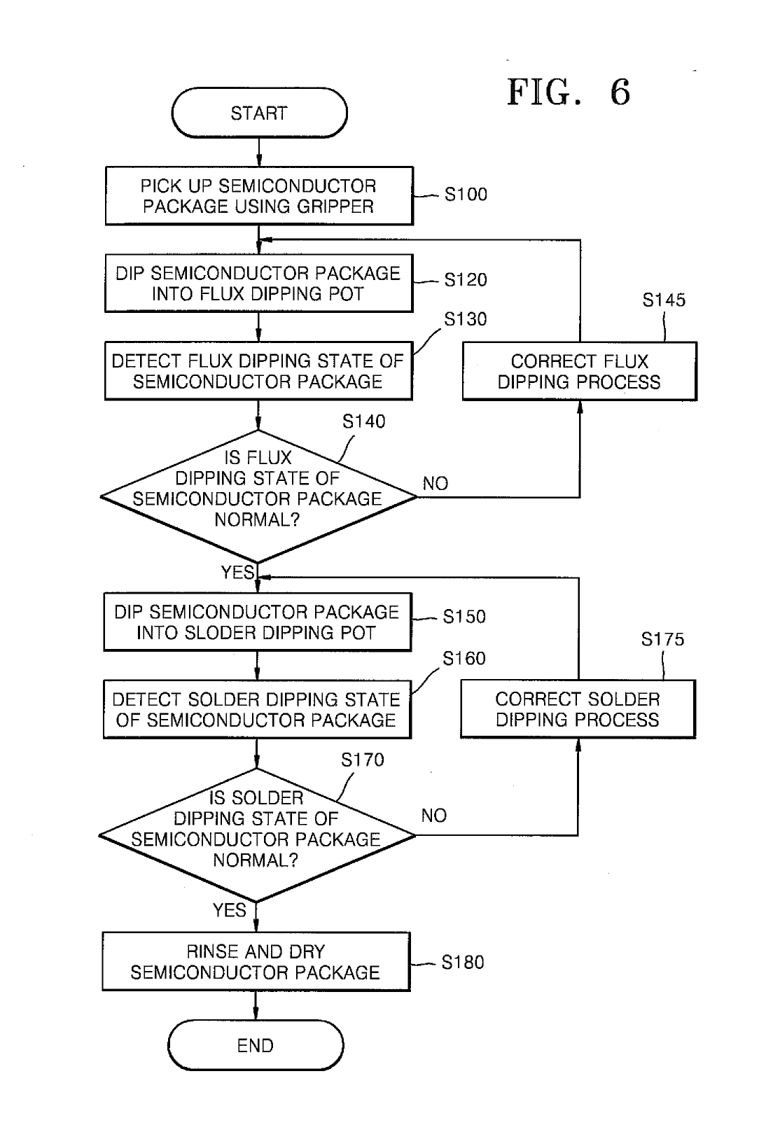

FIG. 5 illustrates dipping soldering equipment according to an embodiment of the present invention including a dipping pot 1300, a rinse device 1500, and a hot dry device 1600. A pick and place device (not shown) moves a semiconductor device that is to be dipped into position so that a gripper can pick up the device. Dipping pot 1300 contains a dipping solution. A rear gripper (not shown) then moves the semiconductor package to rinse device 1500 and hot dry device 1600 dries the rinsed semiconductor package.

The pick and place device picks up a semiconductor package from loading tray 1140 and then loads it onto nest loading tray 1220. Nest loading tray 1220 moves to an appropriate position where gripper 100 picks up the package and moves it to dipping pot 1300 where it is dipped in dipping solution. Dipping pot 1300 includes flux dipping pot 1320 and a solder dipping pot 1340. In an embodiment, the semiconductor package is dipped into the flux of flux dipping pot 1320 and then into solder of solder dipping pot 1340. Air pre-heater 1400 is positioned between flux dipping pot 1320 and solder dipping pot 1340 to preheat the semiconductor package with air. Detection of the dipping state of the device is performed in real-time utilizing dipping detecting device 10 described above with reference to FIGS. 2, 3, and 4. Thus, the dipping soldering equipment solves the problem of not detecting a poor dipping state of a semiconductor device during a dipping process associated with conventional soldering equipment.

Semiconductor packages, which have completely undergone a soldering process, are loaded onto nest moving tray 1240 and then moved to the rear gripper. The rear gripper picks up the semiconductor packages and moves them to rinse device 1500 and hot dry device 1600 so as to rinse and dry the semiconductor packages. The rinsed and dried semiconductor packages are then loaded onto nest unloading tray 1260. The pick and place device picks up the semiconductor packages and moves them to unloading tray 1120 so as to complete the soldering process. Gripper 100 and the rear gripper move the semiconductor packages through moving axis 1700 which includes a vertical axis 1720 and horizontal axis 1740.

If a poor dipping state occurs, the soldering equipment may automatically correct this situation by raising the level of the dipping solution and/or the amount by which gripper 100 is lowered to correct and continue performing the dipping process. In this manner, the dipping process may be rapidly and continuously performed without stopping the operation of the dipping equipment even if a poor dipping state occurs. As a result, the percentage of poor semiconductor package yields can be reduced and the semiconductor packages can be efficiently mass-produced.

FIG. 6 is a flowchart illustrating a method of detecting the dipping state of a semiconductor device using a dipping detecting device according to an embodiment of the present invention. In step S100, gripper 100 picks up semiconductor package 600 which is dipped into the flux of flux dipping pot 1320 at step S120. The dipping state of semiconductor package 600 into the flux is detected at step S130. Step S140 determines whether semiconductor package 600 has been normally dipped into the flux by determining whether current flows as described above. If in step S140 it is determined that semiconductor package 600 has been abnormally dipped into the flux where current does not flow, the flux dipping process is corrected at step S145 and returns to step S120. Correction of the flux dipping process may be performed by raising the level of the dipping solution or increasing the dipping depth of gripper 100 as described above.

If in step S140 it is determined that semiconductor package 600 has been normally dipped into the flux of flux dipping pot 1320 such that current flows, the semiconductor package 600 is dipped into solder dipping pot 1340 in step S150. Semiconductor package 600 may be preheated in pre-heater 1400 before it is dipped into solder dipping pot 1340. In step S160, a solder dipping state is detected by the dipping detecting device and determined whether the solder dipping state is normal in step S170. If the solder dipping state is not normal, the solder dipping process is corrected in step S175 and the process returns to step S150. If it is determined that the solder dipping state is normal, rinsing and drying processes are performed at step S180 on the semiconductor package 600 to complete the process.

In a dipping detecting method according to the present invention the dipping state of a semiconductor device may be determined and corrected. As a result, poor soldering of semiconductor packages can be prevented and mass-production yields can be considerably improved. The dipping detecting method of the present invention may be applied to a soldering process and any semiconductor dipping process using a conductive dipping solution.

Although the present invention has been described in connection with the embodiment of the present invention illustrated in the accompanying drawings, it is not limited thereto. It will be apparent to those skilled in the art that various substitution, modifications and changes may be thereto without departing from the scope and spirit of the invention.

What is claimed is:

1. A dipping detecting device used for fabrication of a semiconductor device comprising:
a gripper used as a conductive first electrode, said gripper configured to pick up the semiconductor device for dipping into a dipping solution;
a conductor used as a second electrode, said conductor formed at a side of said gripper and electrically insulated from said gripper; and
a power source unit applying a power to said gripper and said conductor, said power source unit configured to detect a current flow wherein a dipping state of the semiconductor device is detected depending on whether current flows between said conductor and said gripper when said semiconductor device is dipped in said dipping solution.

2. The dipping detecting device of claim 1 wherein said power source unit comprises a PLC (programmable logical controller) module.

3. The dipping detecting device of claim 1 wherein said power source unit comprises a power source device which applies an AC (alternating current) or a DC (direct current) and an I/O (input/output) device that detects current flow.

4. The dipping detecting device of claim 2 wherein the power source unit comprises a relay switch connected between said conductor and said PLC module.

5. The dipping detecting device of claim 3 wherein the power source unit comprises a relay switch connected between said conductor and said I/O device.

6. The dipping detecting device of claim 4 wherein the power source unit comprises a current filter disposed between said relay switch and said conductor to maintain a constant voltage applied to said relay switch.

7. The dipping detecting device of claim 1 wherein the power source unit comprises:
a power source device having first and second electrodes, said power source device applying AC or DC power;
a capacitor disposed between said first and second electrodes of the power source device and between said gripper and said conductor; and
an I/O device connected to said capacitor and configured to detect whether current flows between said conductor and said gripper.

8. The dipping detecting device of claim 7, wherein the power source device charges said capacitor, when the power source device is turned off during a semiconductor device dipping process, said capacitor supplies power between said gripper and said conductor, and said I/O device measures a voltage drop across said capacitor to detect a dipping state of the semiconductor device.

9. The dipping detecting device of claim 1 wherein the semiconductor device is a semiconductor package that is to be soldered and said dipping solution is a conductive liquid flux.

10. The dipping detecting device of claim 1 wherein the semiconductor device is a semiconductor package that is to be soldered and said dipping solution is a conductive solder.

11. The dipping detecting device of claim 1, wherein a lower part of said conductor contacts said dipping solution when an entire part of the semiconductor device that is to be dipped is dipped into said dipping solution.

12. The dipping detecting device of claim 11, wherein the lower part of said conductor contacts the dipping solution when a top lead of the semiconductor package is dipped into said dipping solution.

13. Dipping equipment used in the fabrication of a semiconductor device comprising:
a dipping detecting device comprising
a gripper used as a conductive first electrode, said gripper configured to pick up the semiconductor device for dipping into a dipping solution;
a conductor used as a second electrode, said conductor formed at a side of said gripper and electrically insulated from said gripper; and
a power source unit applying a power to said gripper and said conductor, said power source unit configured to detect a current flow wherein a dipping state of the semiconductor device is detected depending on whether current flows between said conductor and said gripper when said semiconductor device is dipped in said dipping solution;
a pick and place device moving the semiconductor device to be dipped to a position in which said gripper can pick up the semiconductor device; and
a dipping pot containing said dipping solution.

14. The dipping equipment of claim 13, wherein the semiconductor device is a semiconductor package to be soldered and the dipping equipment is dipping soldering equipment.

15. The dipping equipment of claim 14, wherein the dipping pot comprises a flux dipping pot comprising a conductive liquid flux and a solder dipping pot comprising a liquid solder.

16. The dipping equipment of claim 15, further comprising:
a plurality of loading trays loading the semiconductor package so that said gripper can pick up the semiconductor package;
an air preheater positioned between the flux dipping pot and the solder dipping pot to preheat the semiconductor package, which has been completely dipped into the conductive liquid flux of the flux dipping pot, with air;
a rinse device rinsing a semiconductor package that has been completely dipped into the liquid solder of the solder dipping pot;
a hot dry device for drying the rinsed semiconductor package; and
a rear gripper moving the semiconductor package, which has been completely dipped into the liquid solder of the solder dipping pot, to said rinse device and said hot dry device.

17. The dipping equipment of claim 16, wherein said plurality of loading trays further comprise:
a nest loading tray for loading the semiconductor package through the pick and place device so that said gripper picks up the semiconductor package;
a nest moving tray for loading the semiconductor package, which has been completely dipped into the liquid solder of said solder dipping pot, and moving the semiconductor package so that said rear gripper picks up the semiconductor package; and
a nest unloading tray for loading the rinsed and dried semiconductor package and unloading the semiconductor package utilizing said pick and place device.

18. The dipping equipment of claim 13, wherein said power source unit further comprises a PLC module.

19. The dipping equipment of claim 13, wherein said power source unit further comprises a power source device which applies an AC or a DC and an I/O device that detects current flow.

20. The dipping equipment of claim 18, wherein said power source unit further comprises a relay switch connected to said conductor and said PLC module.

21. The dipping equipment of claim 19, wherein said power source unit further comprises a relay switch connected to said conductor and said I/O device.

22. The dipping equipment of claim 20, wherein said power source unit comprises a current filter between said relay switch and said conductor to maintain a constant voltage applied to said relay switch.

23. The dipping equipment of claim 13, wherein said power source unit further comprises:
a power source device having first and second electrodes, said power source device configured to provide AC or DC power;
an I/O device that detects current flow; and
a capacitor connected between both electrodes of said power source device and between said gripper and said conductor, wherein said I/O device is connected to said capacitor.

24. The dipping equipment of claim 23, wherein the power source device charges said capacitor, when the power source device is turned off during a semiconductor device dipping process, said capacitor supplies power between said gripper and said conductor, and said I/O device measures a voltage drop across said capacitor to detect a dipping state of the semiconductor device.

25. The dipping equipment of claim 13, wherein a lower part of said conductor contacts said dipping solution when an entire part of the semiconductor device that is to be dipped is dipped into said dipping solution.

26. The dipping equipment of claim 25, wherein the dipping detecting device detects a dipping soldering state of a semiconductor package, and the lower part of said conductor contacts said dipping solution when a top lead of the semiconductor package is dipped into said dipping solution.

27. The dipping equipment of claim 13, wherein the dipping equipment automatically adjusts a dipping depth of the gripper or a level of the dipping solution of the dipping pot according to a result of the dipping detecting device.

28. The dipping equipment of claim 13, wherein the dipping equipment comprises a warning device that generates a warning signal if the dipping detecting device detects poor dipping.

29. A method of detecting a dipping state of a semiconductor device, comprising:
picking up the semiconductor device;
dipping the semiconductor device into a dipping solution contained in a dipping pot; and
detecting the dipping state of the semiconductor device using a dipping detecting device.

30. The method of claim 29 wherein said dipping detecting device comprises:
a gripper used as a conductive first electrode, said gripper configured to pick up the semiconductor device for dipping into a dipping solution;
a conductor used as a second electrode, said conductor formed at a side of said gripper and electrically insulated from said gripper; and
a power source unit applying a power to said gripper and said conductor, said power source unit configured to detect a current flow wherein a dipping state of the semiconductor device is detected depending on whether current flows between said conductor and said gripper when said semiconductor device is dipped in said dipping solution.

31. The method of claim 30, after detecting the dipping state of the semiconductor device using the dipping detecting device, said method further comprising:
dipping a semiconductor package, which has been completely dipped into a conductive flux, into a liquid solder contained in a soldering dipping pot using said gripper; and
detecting a soldering dipping state of the semiconductor package using the dipping detecting device, wherein the semiconductor device is the semiconductor package that is to be dipped into the liquid solder, and the dipping solution is the conductive flux.

32. The method of claim 31, before dipping the semiconductor package into the liquid solder, further comprising preheating the semiconductor package, which has been completely dipped into the conductive flux, with air.

33. The method of claim 30, wherein said power source unit comprises a PLC module that detects whether current flows, wherein the dipping state of the semiconductor device is detected depending on whether current flows.

34. The method of claim 30, wherein said power source unit further comprises:
a power source device that applies an alternating or direct current; and
an I/O device that detects whether current flows, wherein the dipping state of the semiconductor device is detected depending on whether current flows.

35. The method of claim 30, wherein said power source unit further comprises:
a power source device having a pair of electrodes, said power source device configured to apply an alternating or direct current;
an I/O device that detects current flow; and
a capacitor connected between both electrodes of said power source device and between said gripper and said conductor, wherein the I/O device is connected to the capacitor.

36. The method of claim 35 further comprising:
charging the capacitor when the process of dipping the semiconductor device is not required;
turning off said power source device during the process of dipping the semiconductor device;
supplying power from said capacitor between said gripper and said conductor during the process of dipping the semiconductor device; and
measuring a voltage drop of the capacitor using said I/O device to detect the dipping state of the semiconductor device.

37. The method of claim 30, wherein a lower part of said conductor contacts said dipping solution when an entire part of the semiconductor device that is to be dipped is dipped into said dipping solution, and
when the lower part of said conductor contacts said dipping solution, said dipping detecting device detects whether current flows so as to detect whether the entire part of the semiconductor device has been dipped into said dipping solution.

38. The method of claim 30, further comprising automatically correcting a dipping process if the dipping state of the semiconductor device is poor.

39. The method of claim 38, further comprising adjusting a level of the dipping solution in said dipping pot to automatically correct the dipping process.

40. The method of claim 38, further comprising adjusting a dipping depth of said gripper into said dipping solution to automatically correct the dipping process.
